(19) United States
(12) Patent Application Publication
(10) Pub. No.: US 2024/0282695 A1
(43) Pub. Date: Aug. 22, 2024

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/231,092

(22) Filed: Aug. 7, 2023

(30) Foreign Application Priority Data
Feb. 22, 2023 (KR) 10-2023-0023757

(51) Int. Cl. H01L 23/522; H01L 21/768; H01L 29/10

(52) U.S. Cl. CPC H01L 23/5226; H01L 21/76802; H01L 21/76843; H01L 21/76877; H01L 29/1037; H10B 41/27; H10B 43/27; H10B 63/84

(57) ABSTRACT

The present technology relates to a semiconductor device and a method of manufacturing the semiconductor device. The semiconductor device includes a stack including a plurality of interlayer insulating layers and a plurality of gate conductive layers alternately stacked, a channel plug formed on a cell region by vertically passing through the stack, a plurality of support structures formed on a contact region by vertically passing through the stack, and a sacrificial layer surrounding a lower end portion sidewall of each of the plurality of support structures.

### CROSS-REFERENCE TO RELATED APPLICATION

The present application claims priority under 35 U.S.C. § 119(a) to Korean patent application number 10-2023-0023757 filed on Feb. 22, 2023, in the Korean Intellectual Property Office, the entire disclosure of which is incorporated by reference herein.

### BACKGROUND

### 1. Technical Field

The present disclosure generally relates to an electronic device, and more particularly, to a semiconductor device and a method of manufacturing the semiconductor device.

### 2. Related Art

A nonvolatile memory element is a memory element in which stored data is maintained even though the power supply is cut off. Recently, as improvement of an integration degree of a two-dimensional nonvolatile memory element that forms a memory cell in a single layer on a substrate has reached a limit, a three-dimensional nonvolatile memory element that vertically stacks memory cells on a substrate has been proposed.

The three-dimensional nonvolatile memory element includes interlayer insulating layers and gate electrodes which are alternately stacked, and channel layers passing through the interlayer insulating layers and the gate electrodes, and memory cells are stacked along the channel layers. Various structures and manufacturing methods have been developed to improve reliability of the nonvolatile memory element having such a three-dimensional structure.

### SUMMARY

According to an embodiment of the present disclosure, a semiconductor device includes a stack including a plurality of interlayer insulating layers and a plurality of gate conductive layers alternately stacked, a channel plug formed on a cell region by vertically passing through the stack, a plurality of support structures formed on a contact region by vertically passing through the stack, and a sacrificial layer surrounding a lower end portion sidewall of each of the plurality of support structures.

According to an embodiment of the present disclosure, a semiconductor device includes a stack including a plurality of interlayer insulating layers and a plurality of gate conductive layers alternately stacked, a channel plug formed on the cell region by vertically passing through the stack, a plurality of support structures formed on a contact region by vertically passing through the stack, a plurality of contact plugs formed on the contact region by vertically passing through the stack, and a sacrificial layer contacting a lower end portion sidewall of each of the plurality of support structures and a lower end portion sidewall of each of the contact plugs and having a line shape by extending in a horizontal direction.

According to an embodiment of the present disclosure, a method of manufacturing a semiconductor device includes forming a lower end stack in which a plurality of first lower end material layers and at least one second lower end material layer are alternately stacked on a substrate including a cell region and a contact region, forming a plurality of trenches passing through the lower end stack on the contact region, forming a sacrificial layer in the plurality of trenches, forming an upper end stack in which a plurality of first upper end material layers and a plurality of second upper end material layers are alternately stacked on the sacrificial layer and the lower end stack, and forming first holes for forming a contact plug, trenches for forming a first support structure, and second holes for forming a second support structure passing through the upper end stack and the sacrificial layer on the contact region, together.

### BRIEF DESCRIPTION OF THE DRAWINGS

FIGS. 1A and 1B are block diagrams schematically illustrating semiconductor devices according to embodiments of the present disclosure.

FIG. 2 is a cross-sectional view schematically illustrating a peripheral circuit structure.

FIGS. 3A and 3B are plan and cross-sectional views of a semiconductor device illustrating a semiconductor device according to an embodiment of the present disclosure.

FIGS. 4A, 4B, 5, 6A, 6B, 7A, 7B, 8, 9A, 9B, 10, 11A, 11B, and 12 are cross-sectional and plan views illustrating a method of manufacturing a semiconductor device according to an embodiment of the present disclosure.

FIG. 13 is a block diagram illustrating a configuration of a memory system according to an embodiment of the present disclosure.

### DETAILED DESCRIPTION

Specific structural or functional descriptions of embodiments according to the concept which are disclosed in the present specification or application are illustrated to describe the embodiments according to the concept of the present disclosure. The embodiments according to the concept of the present disclosure may be carried out in various forms and should not be construed as being limited to the embodiments described in the present specification or application.

Hereinafter, embodiments of the present disclosure will be described in detail with reference to the accompanying drawings, so that those skilled in the art to which the present disclosure pertains may carry out the technical spirit of the present disclosure.

An embodiment of the present disclosure provides a semiconductor device having a stable structure and an improved characteristic, and a method of manufacturing the semiconductor device.

According to an embodiment of the present technology, a semiconductor device having a stable structure may be manufactured, and thus a characteristic of the semiconductor device may be improved.

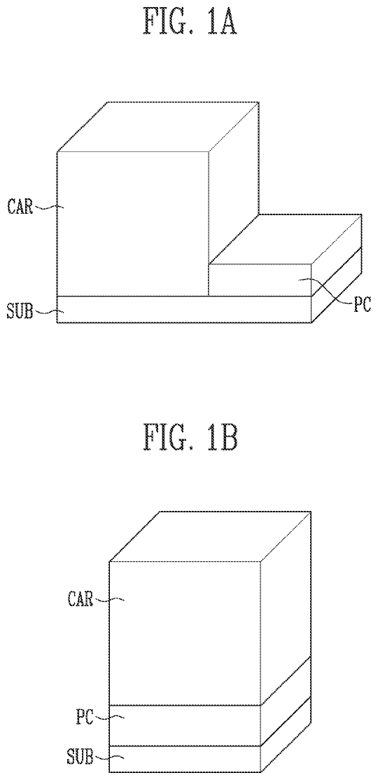

FIGS. 1A and 1B are block diagrams schematically illustrating semiconductor devices according to embodiments of the present disclosure.

Referring to FIGS. 1A and 1B, each of the semiconductor devices according to embodiments of the present disclosure may include a peripheral circuit structure PC and a cell array CAR disposed on a substrate SUB.

The substrate SUB may be a single crystal semiconductor layer. For example, the substrate SUB may be a bulk silicon substrate, a silicon on insulator substrate, a germanium substrate, a germanium on insulator substrate, a silicon-germanium substrate, or an epitaxial thin layer formed through a selective epitaxial growth method.

The cell array CAR may include a plurality of memory blocks. Each of the memory blocks may include a plurality of cell strings. Each of the cell strings is electrically connected to a bit line, a source line, word lines, and select lines. Each of the cell strings may include memory cells and select transistors connected in series. Each of the select lines is used as a gate electrode of a select transistor corresponding thereto, and each of the word lines is used as a gate electrode of a memory cell corresponding thereto.

The peripheral circuit structure PC may include NMOS transistors and PMOS transistors electrically connected to the cell array CAR, a resistor, and a capacitor. The NMOS and PMOS transistors, the resistor, and the capacitor may be used as elements configuring a row decoder, a column decoder, a page buffer, and a control circuit.

As shown in FIG. 1A, the peripheral circuit structure PC may be disposed on a partial region of the substrate SUB, which does not overlap the cell array CAR.

Alternatively, as shown in FIG. 1B, the peripheral circuit structure PC may be disposed between the cell array CAR and the substrate SUB. In this case, in an embodiment, since the peripheral circuit structure PC overlaps the cell array CAR, the area of the substrate SUB occupied by the cell array CAR and the peripheral circuit structure PC may be reduced.

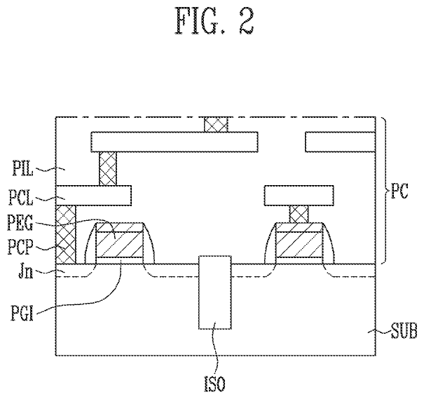

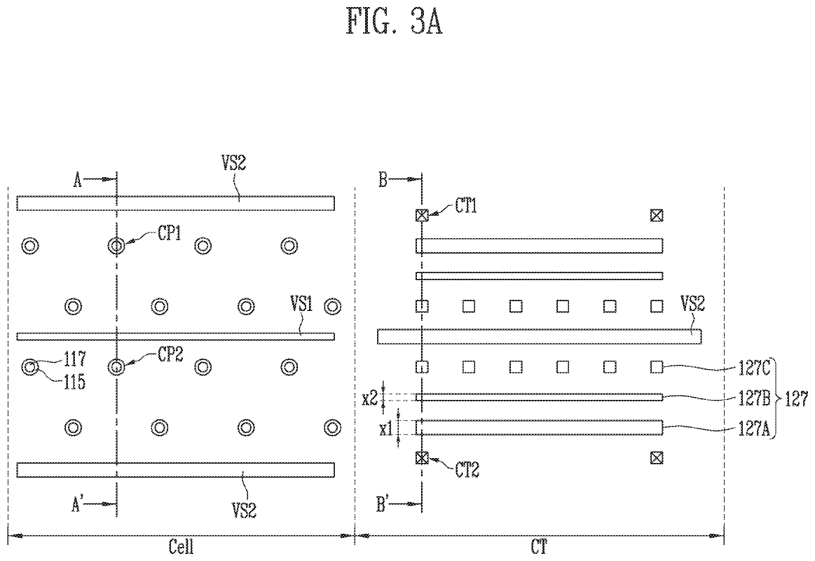

FIG. 2 is a cross-sectional view schematically illustrating a peripheral circuit structure.

The peripheral circuit structure PC shown in FIG. 2 may be included in the peripheral circuit structure shown in FIG. 1A or may be included in the peripheral circuit structure shown in FIG. 1B.

Referring to FIG. 2, the peripheral circuit structure PC may include peripheral gate electrodes PEG, a peripheral gate insulating layer PGI, junctions Jn, peripheral circuit lines PCL, and peripheral contact plugs PCP. The peripheral circuit structure PC may be covered with a peripheral circuit insulating layer PIL formed on the substrate SUB.

Each of the peripheral gate electrodes PEG may be used as gate electrodes of the NMOS transistor and a PMOS transistor of the peripheral circuit structure PC. The peripheral gate insulating layer PGI is disposed between each of the peripheral gate electrodes PEG and the substrate SUB.

The junctions Jn are regions defined by implanting an n-type or p-type impurity into an active region of the substrate SUB, are disposed on both sides of each of the peripheral gate electrodes PEG, and are used as a source junction or a drain junction. The active region of the substrate SUB may be partitioned by an isolation layer ISO formed in the substrate SUB. The isolation layer ISO is formed of an insulating material.

The peripheral circuit lines PCL may be electrically connected to the transistors, the resistor, and the capacitor configuring a circuit of the peripheral circuit structure PC through the peripheral contact plugs PCP.

The peripheral circuit insulating layer PIL may include insulating layers stacked in multiple layers.

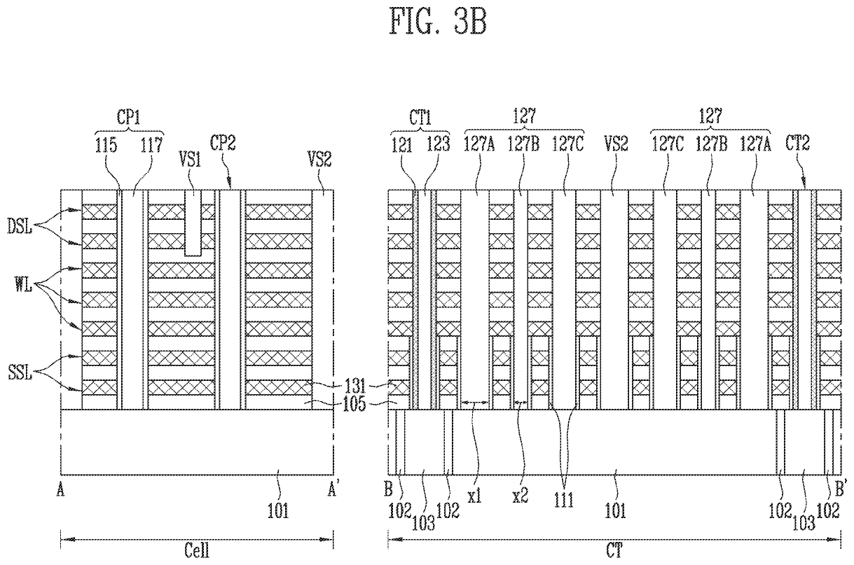

FIGS. 3A and 3B are plan and cross-sectional views of a semiconductor device illustrating a semiconductor device according to an embodiment of the present disclosure.

Referring to FIG. 3A, the cell array CAR of FIGS. 1A and 1B of the semiconductor device may include a cell region Cell and a contact region CT. A plurality of channel plugs CP1 and CP2 may be regularly arranged on the cell region Cell. In addition, a first vertical structure VS1 of a line shape disposed between the plurality of channel plugs CP1 and CP2 may be arranged in a central portion of the cell region Cell, and a second vertical structure VS2 may be disposed at both ends of the cell region Cell. The plurality of channel plugs CP1 and CP2 may be arranged between the second vertical structures VS2. Each of the plurality of channel plugs CP1 and CP2 may include a channel layer 117 and a memory layer 115 surrounding the channel layer 117. The first vertical structure VS1 and the second vertical structure VS2 may be an insulating layer, and may be formed of, for example, an oxide layer. In an embodiment, the second vertical structure VS2 may be disposed at either end of the cell region Cell as shown in FIGS. 3A and 3B. In an embodiment, as shown in FIG. 3B, the second vertical structure VS2 may pass through the stack 131 and 105.

A plurality of contact plugs CT1 and CT2 may be regularly arranged on the contact region CT. In addition, at least one support structure 127 and the second vertical structure VS2 may be arranged in a space between the plurality of contact plugs CT1 and CT2 on the contact region CT. The support structure 127 may be formed of the same material as the first vertical structure VS1. The support structure 127 may be an insulating layer, and may be formed of, for example, an oxide layer. The support structure 127 may include a first support structure 127A and a second support structure 127B of a line shape, and third support structures 127C of a hole shape. A width X1 of the first support structure 127A may be wider than a width X2 of the second support structure 127B. In an embodiment, widths of each of the first support structures 127A of a plurality of first support structures 127A may be different from each other. That is, the support structure 127 may include the support structures of the line shape and the support structures of the hole shape having different widths. The first support structure 127A and the second support structure 127B of the line shape and the third support structure 127C of the hole shape are disposed to be parallel to the second vertical structure VS2 and do not intersect and overlap each other. For example, in an embodiment, the first support structure 127A and the second support structure 127B of the line shape and the third support structure 127C of the hole shape are disposed to be parallel to the second vertical structure VS2 and do not intersect and overlap each other as shown in FIG. 3A.

Referring to FIG. 3B, a cross-section A-A′ is a cross-section of the cell region, and a cross-section B-B′ is a cross-section of the contact region CT.

On the cell region Cell of the semiconductor device, a source line layer 101, a stack 105 and 131 stacked on the source line layer 101, the channel plugs CP1 and CP2 contacting the source line layer 101 by passing through the stack 105 and 131 in a vertical direction, the second vertical structures VS2 vertically disposed on both ends of the stack 105 and 131 and contacting the source line layer 101, and the first vertical structure VS1 disposed by passing through a portion of an upper end of the stack 105 and 131 disposed between the channel plugs CP1 and CP2 may be included and configured.

The source line layer 101 may be a doped semiconductor layer. For example, the source line layer 101 may be a semiconductor layer doped with an n-type impurity. As an embodiment, the source line layer 101 may be formed by implanting an impurity into a surface of the substrate SUB shown in FIG. 1A, or may be formed by depositing at least one doped silicon layer on the substrate SUB. As an embodiment, the source line layer 101 may be formed by forming an insulating layer on the peripheral circuit structure PC shown in FIG. 1B and then depositing at least one doped silicon layer on the insulating layer.

The stack 105 and 131 has a structure in which a plurality of gate conductive layers 131 and an interlayer insulating layer 105 are alternately stacked, and have a structure in which the interlayer insulating layer 105 is disposed at the lowermost end and the uppermost end of the stack 105 and 131. At least one gate conductive layer disposed at the lowermost end of the gate conductive layers 131 may be a source select line SSL, at least one gate conductive layer disposed at the uppermost end of the gate conductive layers 131 is a drain select line DSL, and the remaining gate conductive layers may be word lines WL.

The channel plugs CP1 and CP2 may be vertically arranged by passing through the stack 105 and 131, and may include the channel layer 117 and the memory layer 115 surrounding the channel layer 117.

The first vertical structure VS1 may be disposed to pass through the at least one gate conductive layer 131 that is used as the drain select line DSL and disposed at the uppermost portion of the stack 105 and 131 disposed between the channel plugs CP1 and CP2. That is, the first vertical structure VS1 electrically separates the gate conductive layer 131 for the drain select line DSL connected to the first channel plug CP1 and the gate conductive layer 131 for the drain select line DSL connected to the second channel plug CP2. In an embodiment, the first vertical structure VS1 of a line shape passes through an upper portion of the stack at a central portion of the cell region as shown in FIG. 3B.

On the contact region CT of the semiconductor device, the source line layer 101, a contact pad layer 103, an isolation layer 102 disposed between the source line layer 101 and the contact pad layer 103, the stack 105 and 131 stacked on the isolation layer 102 and the contact pad layer 103, the contact plugs CT1 and CT2 contacting the contact pad layer 103 by passing through the stack 105 and 131 in the vertical direction, the second vertical structure VS2 contacting the source line layer 101 by passing through the stack 105 and 131 in the vertical direction, and at least one support structure 127 may be included and configured. In an embodiment, the plurality of interlayer insulating layers 105 and a plurality of gate conductive layers 131 may be alternately stacked in a vertical direction as shown in FIG. 3B.

The source line layer 101 and the contact pad layer 103 are formed on the same layer, and the source line layer 101 and the contact pad layer 103 are electrically separated from each other by the isolation layer 102 disposed between the source line layer 101 and the contact pad layers 103. The isolation layer 102 may be formed of an insulating layer, for example, an oxide layer. The contact pad layer 103 may be electrically connected to the peripheral circuit structure PC shown in FIGS. 1A and 1B.

Each of the contact plugs CT1 and CT2 may include a conductive layer 123 for a contact plug and a barrier layer 121 surrounding the conductive layer 123 for the contact plug. The barrier layer 121 may also be formed on a sidewall of the support structures 127.

A sacrificial layer 111 is formed on a lower end portion sidewall of the support structures 127. That is, the sacrificial layer 111 may be formed to contact the lower end portion sidewall of the support structures 127. For example, the sacrificial layer 111 is formed on a lower end portion sidewall of the first support structure 127A and the second support structure 127B of the line shape, and the lower end portion sidewall of the first support structure 127A and the second support structure 127B is physically spaced apart from the lower end portion of the stack 105 and 131. The sacrificial layer 111 may extend in a horizontal direction along the lower end portion sidewall of the first support structure 127A and the second support structure 127B, and may have a line shape extending in the same direction as the first support structure 127A and the second support structure 127B.

A lower end portion of the third support structure 127C passes through the sacrificial layer 111 of the line shape. Accordingly, the sacrificial layer 111 surrounds a lower end portion sidewall of the third support structure 127C. In an embodiment, the lower end portion sidewall of the support structures 127 is towards the source line layer 101 as shown in FIG. 3B.

The sacrificial layer 111 may be formed to surround the lower end portion sidewall of the contact plugs CT1 and CT2, In addition, the sacrificial layer 111 may be formed to contact a lower end portion sidewall of the second vertical structure VS2. The sacrificial layer 111 may include an oxide layer.

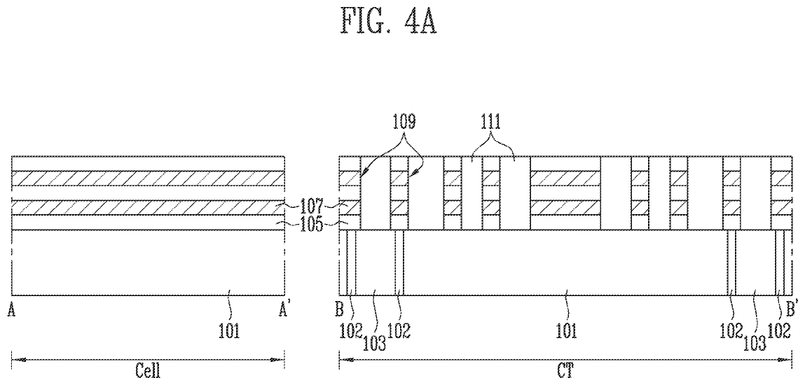

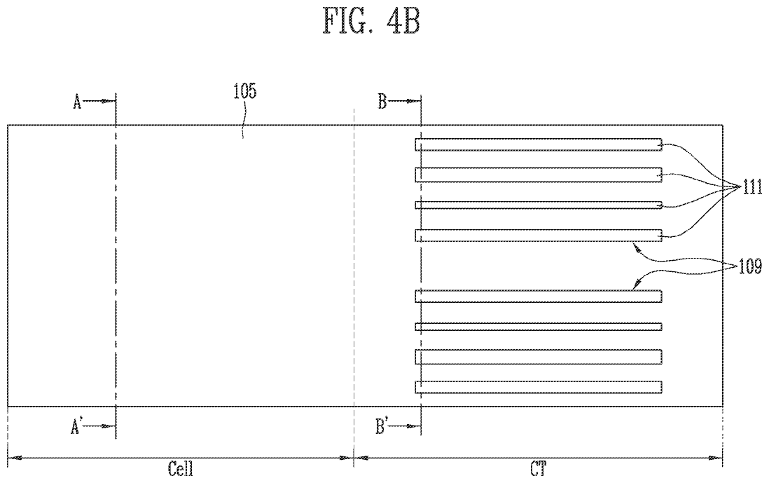

FIGS. 4A, 4B, 5, 6A, 6B, 7A, 7B, 8, 9A, 9B, 10, 11A, 11B, and 12 are cross-sectional and plan views illustrating a method of manufacturing a semiconductor device according to an embodiment of the present disclosure.

Referring to FIGS. 4A and 4B, the source line layer 101 is formed on the cell region Cell and the contact region CT of the semiconductor device. The source line layer 101 may be a doped semiconductor layer, for example, a semiconductor layer doped with an n-type impurity. As an embodiment, the source line layer 101 may be formed by implanting an impurity into the surface of the substrate SUB shown in FIG. 1A or by depositing at least one doped silicon layer on the substrate SUB. As an embodiment, the source line layer 101 may be formed by forming an insulating layer on the peripheral circuit structure PC shown in FIG. 1B and then depositing at least one doped silicon layer on the insulating layer.

Thereafter, a portion of the source line layer 101 formed on the contact region CT is etched to form a region in which the contact pad layer is to be formed. The region in which the contact pad layer is to be formed may be defined as a region electrically connected to the peripheral circuit structure PC shown in FIGS. 1A and 1B. Thereafter, the contact pad layer 103 is formed in a portion where the source line layer 101 is etched and removed. The isolation layer 102 is formed between the contact pad layer 103 and the source line layer 101 to electrically separate the contact pad layer 103 and the source line layer 101. The isolation layer 102 may be formed of an insulating layer, for example, an oxide layer.

Thereafter, the stack 105 and 107 in which first material layers 105 and second material layers 107 are alternately stacked are formed on the cell region Cell and the contact region CT. The stack 105 and 107 formed in FIG. 4A may be defined as a lower end stack.

The second material layers 107 may be for forming conductive layers such as a word line, a select line, and a pad, and the first material layers 105 may be for insulating the stacked conductive layers from each other.

The first material layers 105 are formed of a material having a high etching selectivity with respect to the second material layers 107. For example, the first material layers 105 may include an insulating material such as oxide, and the second material layers 107 may include a sacrificial material such as nitride.

Thereafter, trenches 109 of a line shape passing through the stack 105 and 107 formed in the contact region CT are formed. A bottom surface of the trenches 109 may expose the source line layer 101 of the contact region CT. In addition, a bottom surface of some of the trenches 109 may expose the contact pad layer 103 of the contact region CT.

Thereafter, the sacrificial layer 111 is formed so that an inside of the trenches 109 is buried. The sacrificial layer 111 may include an oxide layer.

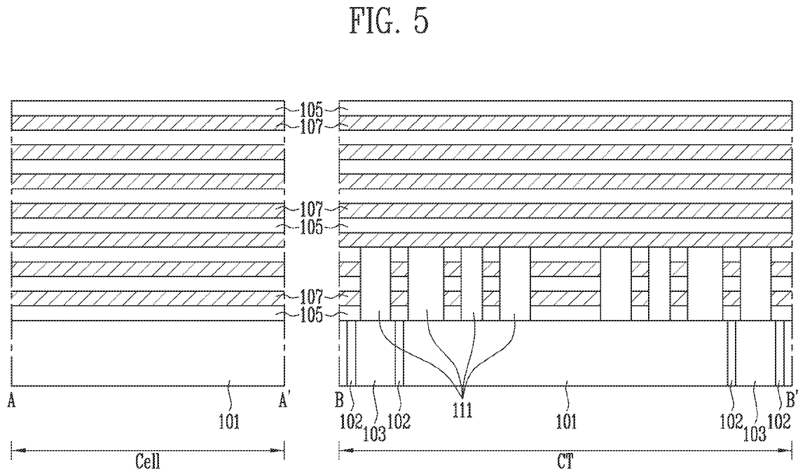

Referring to FIG. 5, the first material layers 105 and the second material layers 107 are alternately stacked on the entire region of the cell region Cell and the contact region CT of the semiconductor device. The first material layers 105 and the second material layers 107 formed on the sacrificial layer 111 of the contact region CT may be defined as an upper end stack. That is, the upper end stack may be formed on the lower end stack formed in the contact region CT and the sacrificial layer 111.

The second material layers 107 may be used to form conductive layers such as a word line, a select line, and a pad, and the first material layers 105 may be used to insulate stacked conductive layers from each other.

The first material layers 105 are formed of a material having a high etching selectivity with respect to the second material layers 107. For example, the first material layers 105 may include an insulating material such as oxide, and the second material layers 107 may include a sacrificial material such as nitride.

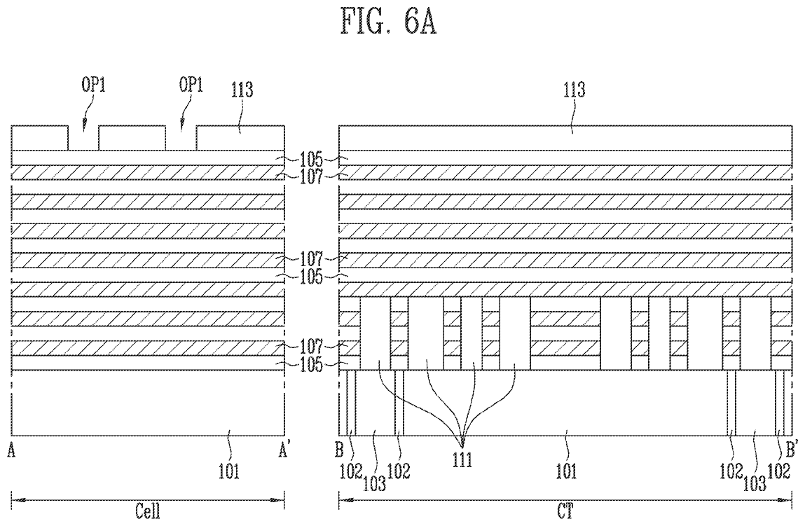

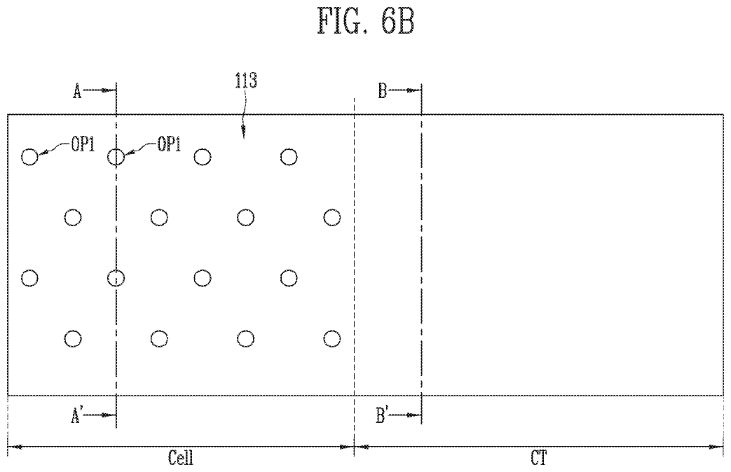

Referring to FIGS. 6A and 6B, a first mask pattern 113 is formed on the stack 105 and 107 of the cell region Cell and the contact region CT. The first mask pattern 113 is formed so that a portion where the channel plug is to be formed in the cell region Cell has a first opening OP1.

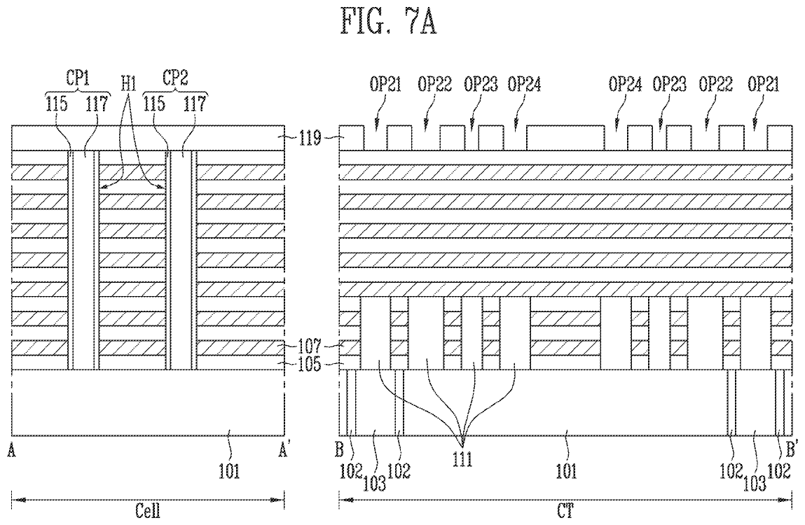

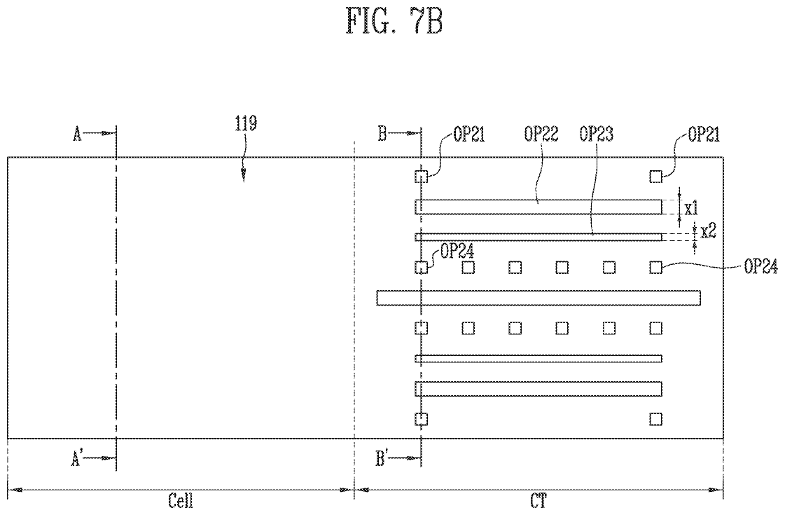

Referring to FIGS. 7A and 7B, the stack 105 and 107 is etched by using the first mask pattern as a barrier to form first holes H1 passing through the stack 105 and 107 formed in the cell region Cell. At this time, the contact region CT is not etched by the first mask pattern, and thus a hole is not formed.

Thereafter, the first mask pattern is removed.

Thereafter, the channel plugs CP1 and CP2 including the channel layer 117 and the memory layer 115 surrounding the channel layer 117 are formed in the first holes H1. For example, the memory layer 115 is formed on a sidewall of the first holes H1. The memory layer 115 may include at least one of a charge blocking layer, a data storage layer, and a tunnel insulating layer, and the data storage layer may include a floating gate such as silicon, a charge trap material such as nitride, a phase change material, a nano dot, or the like. Thereafter, the channel plugs CP1 and CP2 are formed by filling the first holes H1 with the channel layer 117 up to a central region. As another embodiment, the channel layer 117 may be formed in a structure in which the central region of the first holes H1 is open, and a gap-fill layer may be formed in the opened central region.

Thereafter, a second mask pattern 119 is formed on the channel plugs CP1 and CP2 and the stack 105 and 107 of the cell region Cell and on the stack 105 and 107 of the contact region CT. The second mask pattern 119 is formed so that a portion where the contact plug is to be formed and a portion where the support structure is to be formed in the contact region CT have second openings OP21 to OP24. For example, the second opening OP21 corresponding to the contact plug may have a hole type, and the second openings OP22, OP23, and OP24 corresponding to the support structure may have a line type and a hole type. Widths X1 and X2 of the second openings OP22 and OP23 of the line type may be different from each other. The second opening OP24 corresponding to the support structure may have a hole type. In an embodiment, the upper portion of the stack 105 and 131 is towards the uppermost interlayer insulating layer 105 as shown in FIG. 3B.

In an embodiment of the present disclosure, an example in which the support structure is formed in the line shape and the hole type of a quadrangle structure is described, but the present disclosure is not limited thereto, and the support structure may be formed in various patterns such as a circle, an ellipse, a rhombus, and the like.

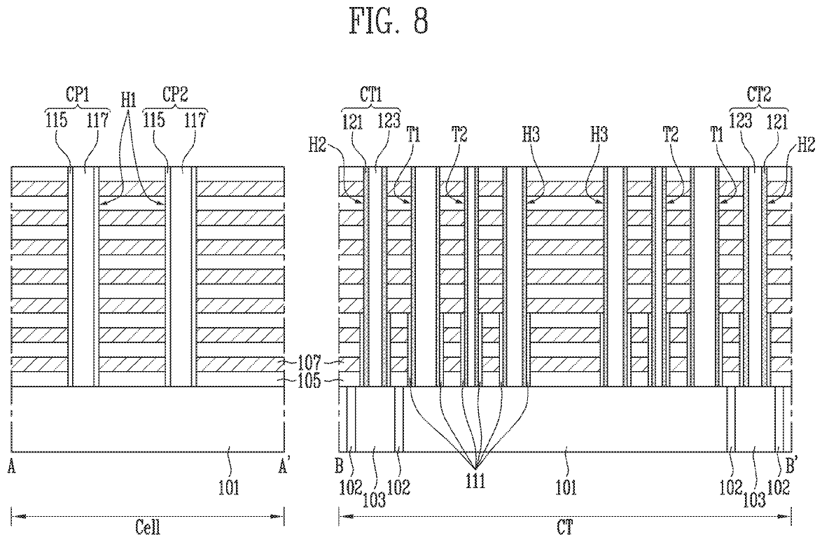

Referring to FIG. 8, the sacrificial layer 111 is exposed by etching the upper stack 105 and 107 on the contact region CT using the second mask pattern as a barrier. Thereafter, the exposed sacrificial layer 111 is etched to form second holes H2 and third holes H3 passing through the upper stack 105 and 107 and the sacrificial layer 111, the first and second trenches T1 and T2 of the line shape.

During a process of forming the second holes H2, the third holes H3, and the first and second trenches T1 and T2 of the line shape described above, the upper stack 105 and 107 may be etched to expose the sacrificial layer 111, and then the exposed sacrificial layer 111 may be additionally etched to form the second holes H2, the third holes H3, and the first and second trenches T1 and T2 of the line shape so that the second holes H2, the third holes H3, and the first and second trenches T1 and T2 of the line shape have a uniform depth.

Thereafter, the second mask pattern may be removed.

Thereafter, a barrier layer 121 is formed on a sidewall of the second holes H2, and the plugs CT1 and CT2 connected to the contact pad layer 103 are formed by filling an inside of the second holes H2 with the conductive layer 123 for the contact plug. At this time, the barrier layer 121 and the conductive layer 123 for the contact plug may also be formed inside the third holes H3 and the first and second trenches T1 and T2 of the line shape.

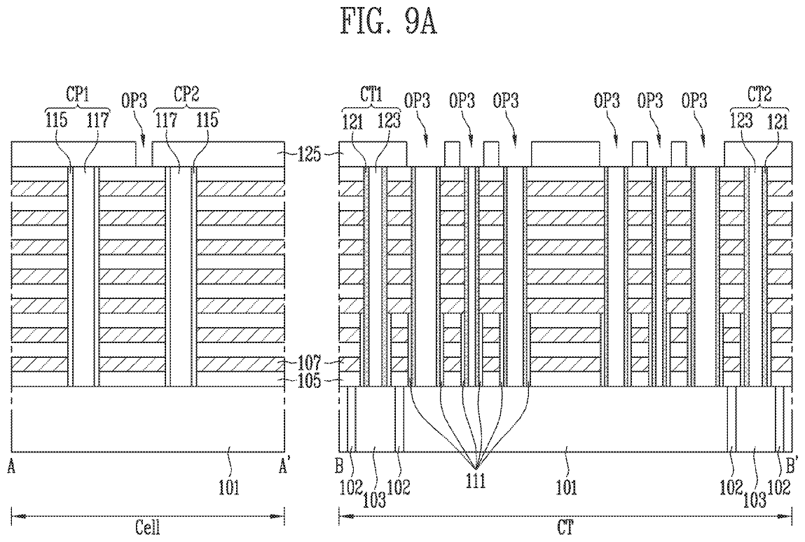

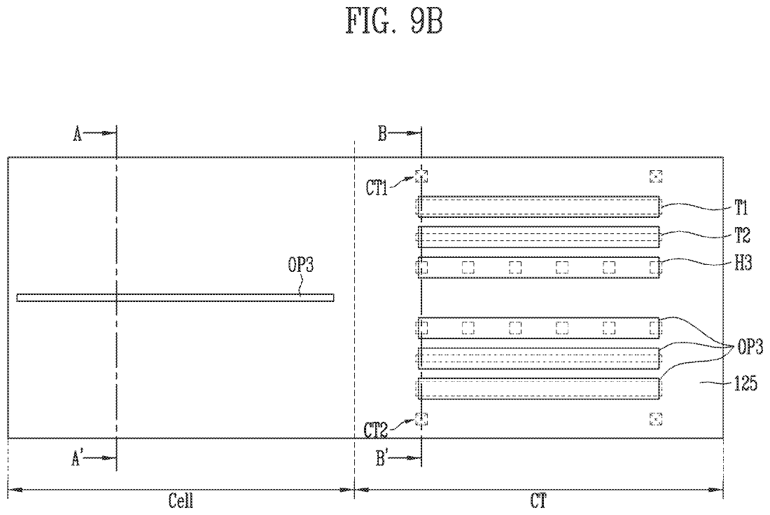

Referring to FIGS. 9A and 9B, a third mask pattern 125 is formed on the channel plugs CP1 and CP2 and the stack 105 and 107 of the cell region Cell, and the contact plugs CT1 and CT2 and the stack 105 and 107 of the contact region CT. The third mask pattern 125 is formed to have a third opening OP3 in which a partial region is opened among a region between the channel plugs CP1 and CP2 in the cell region Cell and a region where the support structure of the contact region CT is to be formed. That is, the third mask pattern 125 is formed to have the third opening OP3 through which the region where the first vertical structure between the channel plugs CP1 and CP2 is to be formed and a portion of the region where the support structure is to be formed are opened. The third opening OP3 of the region where the first vertical structure is to be formed may be formed in a line shape as shown in FIG. 9B.

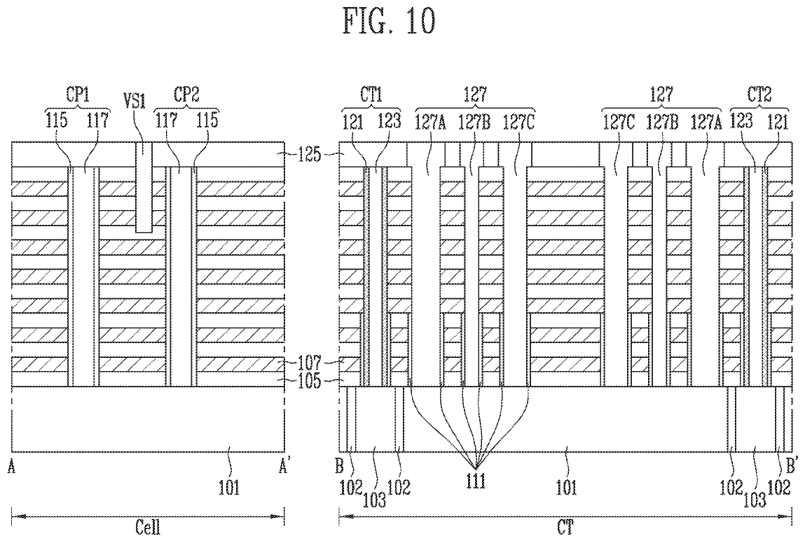

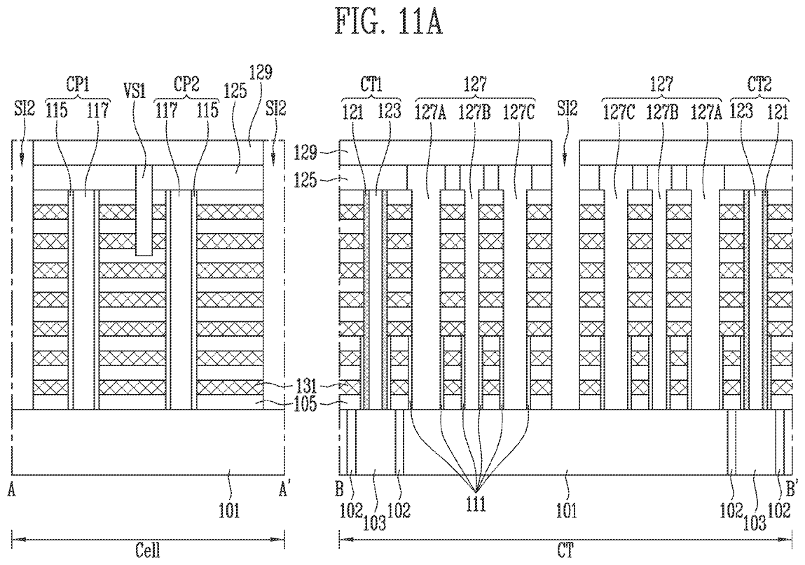

Referring to FIG. 10, a portion of an upper end portion of the stack 105 and 107 formed between the channel plugs CP1 and CP2 of the cell region Cell is etched using the third mask pattern 125 as a mask pattern to form a first slit, and an insulating layer is filled in the first slit to form the first vertical structure VS1. The first vertical structure VS1 is formed to pass through at least one second material layer 107 disposed at the uppermost end of the stack 105 and 107 where the drain select line is to be formed.

Thereafter, in the contact region CT, the conductive layer 123 for the contact plug and the barrier layer 121 formed in the first trench, the second trench, and the third hole exposed through the third opening OP3 of FIGS. 9A and 9B of the third mask pattern 125 are removed. Thereafter, an insulating layer is filled in the first trench, the second trench, and the third hole to form the first support structure 127A, the second support structure 127B, and the third support structures 127C.

A process of removing the conductive layer 123 for the contact plug and the barrier layer 121 described above may be performed after an etching process for forming the first slit in the cell region Cell using the third mask pattern 125 as a mask pattern. In addition, a process of filling the insulating layer in the first trench, the second trench, and the third hole may be performed together with a process of filling the insulating layer in the first slit. The first vertical structure VS1 and the supporting structures 127 may be formed of an oxide layer.

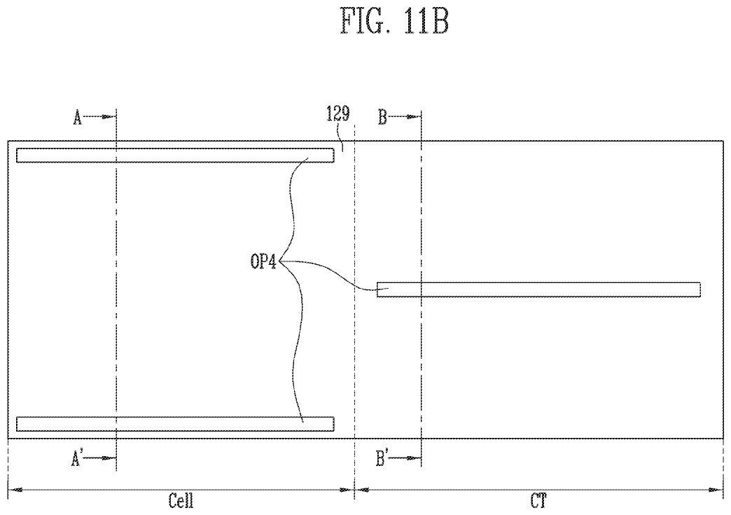

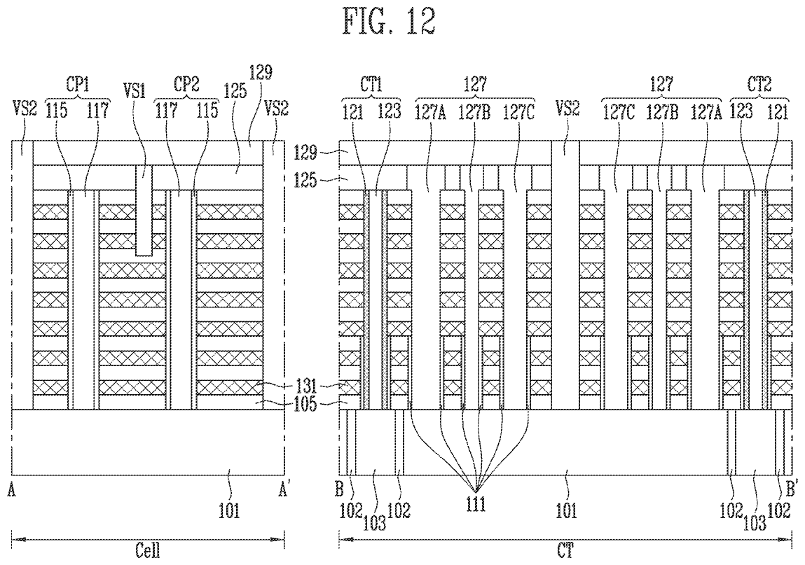

Referring to FIGS. 11A and 11B, a fourth mask pattern 129 is formed on the third mask pattern 125 on the cell region Cell and the contact region CT. The fourth mask pattern 129 is formed to have a fourth opening OP4 through which both ends of a region where the channel plugs CP1 and CP2 are disposed in the cell region Cell and a region between the support structures 127 of the contact region CT are opened. That is, the fourth mask pattern 129 is formed to have the fourth opening OP4 through which a region where the second vertical structure is to be formed at both ends of the region where the channel plugs CP1 and CP2 are disposed and a region where the second vertical structure is to be formed between the support structures 127. The fourth openings OP4 of the region where the second vertical structures are to be formed may be formed in a line shape as shown in FIG. 11B and may be disposed to be parallel to or perpendicular to each other. In addition, the fourth openings OP4 may be formed in various shapes according to an embodiment.

Thereafter, the auxiliary support structure 127 and the stack 105 and 107 of FIG. 9 formed at both ends of the region where the channel plugs CP1 and CP2 of the cell region Cell are disposed, and the third mask pattern 125 and the stack 105 and 107 of FIG. 10 formed between the support structures 127 of the contact region CT are etched using the fourth mask pattern 129 as a barrier to form second slits SI2. The second slits SI2 etch the stack 105 and 107 of FIG. 10 to expose a sidewall of the first material layer 105 and the second material layer 107 of FIG. 10.

Thereafter, the second material layers 107 of FIG. 10 of which the sidewall is exposed through the second slit SI2 are removed, and the gate conductive layers 131 are formed in a space where the second material layers 107 of FIG. 10 are removed. At least one gate conductive layer 131 disposed at the lowermost end of the gate conductive layers 131 is a lower select line (source select line), at least one gate conductive layer 131 disposed at the uppermost end and separated by the first vertical structure VS1 is an upper select line (drain select line), and the remaining gate conductive layers 131 are word lines.

Referring to FIG. 12, the second vertical structures VS2 are formed by filling the second slits with an insulating layer. The second vertical structures VS2 may be formed of an oxide layer.

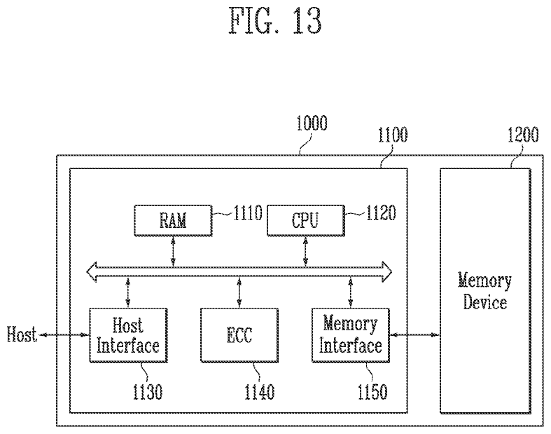

FIG. 13 is a block diagram illustrating a configuration of a memory system according to an embodiment of the present disclosure.

Referring to FIG. 13, the memory system 1000 according to an embodiment of the present disclosure includes a memory device 1200 and a controller 1100.

The memory device 1200 is used to store data information having various data types such as a text, a graphic, and a software code. The memory device 1200 may be the semiconductor device described with reference to FIGS. 1A, 1B, 2, 3A, and 3B. Since a structure of the memory device 1200 and a method of manufacturing the memory device 1200 are the same as described above, a detailed description thereof will be omitted.

The controller 1100 is connected to a host and the memory device 1200 and is configured to access the memory device 1200 in response to a request from the host. For example, the controller 1100 is configured to control read, write, erase, and background operations, and the like of the memory device 1200.

The controller 1100 includes a random access memory (RAM) 1110, a central processing unit (CPU) 1120, a host interface 1130, an error correction code circuit 1140, a memory interface 1150, and the like.

Here, the RAM 1110 may be used as an operation memory of the CPU 1120, a cache memory between the memory device 1200 and the host, a buffer memory between the memory device 1200 and the host, and the like. For reference, the RAM 1110 may be replaced with a static random access memory (SRAM), a read only memory (ROM), or the like.

The CPU 1120 is configured to control overall operation of the controller 1100. For example, the CPU 1120 is configured to operate firmware such as a flash translation layer (FTL) stored in the RAM 1110.

The host interface 1130 is configured to perform interfacing with the host. For example, the controller 1100 communicates with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, and a private protocol.

The ECC circuit 1140 is configured to detect and correct an error included in data read from the memory device 1200 using an error correction code (ECC).

The memory interface 1150 is configured to perform interfacing with the memory device 1200. For example, the memory interface 1150 includes a NAND interface or a NOR interface.

For reference, the controller 1100 may further include a buffer memory (not shown) for storing data. Here, the buffer memory may be used to store data transferred to the outside through the host interface 1130, or to temporarily store data transferred from the memory device 1200 through the memory interface 1150. In addition, the controller 1100 may further include a ROM that stores code data for interfacing with the host.

As described above, since the memory system 1000 according to an embodiment of the present disclosure includes the memory device 1200 having an improved degree of integration and an improved characteristic, a degree of integration and a characteristic of the memory system 1000 may also be improved.

What is claimed is:

1. A semiconductor device comprising:
a stack including a plurality of interlayer insulating layers and a plurality of gate conductive layers alternately stacked;
a channel plug formed on a cell region by vertically passing through the stack;
a plurality of support structures formed on a contact region by vertically passing through the stack; and
a sacrificial layer surrounding a lower end portion sidewall of each of the plurality of support structures.

2. The semiconductor device of claim 1, wherein the plurality of support structures each include a first support structure of a line type and a second support structure of a hole type.

3. The semiconductor device of claim 1, further comprising:
a contact plug formed on the contact region by vertically passing through the stack.

4. The semiconductor device of claim 3, wherein the sacrificial layer surrounds a lower end portion sidewall of the contact plug.

5. The semiconductor device of claim 1, further comprising:
a first vertical structure of a line shape passing through an upper portion of the stack at a central portion of the cell region; and
a second vertical structure of a line shape passing through the stack at both ends of the cell region.

6. The semiconductor device of claim 1, further comprising:
a third vertical structure extending in a horizontal direction by vertically passing through the stack on the contact region.

7. The semiconductor device of claim 6, wherein the sacrificial layer contacts a lower end portion sidewall of the third vertical structure.

8. The semiconductor device of claim 1, wherein the sacrificial layer includes an oxide layer.

9. A semiconductor device comprising:
a stack including a plurality of interlayer insulating layers and a plurality of gate conductive layers alternately stacked;
a channel plug formed on the cell region by vertically passing through the stack;
a plurality of support structures formed on a contact region by vertically passing through the stack;
a plurality of contact plugs formed on the contact region by vertically passing through the stack; and
a sacrificial layer contacting a lower end portion sidewall of each of the plurality of support structures and a lower end portion sidewall of each of the contact plugs and having a line shape by extending in a horizontal direction.

10. The semiconductor device of claim 9, wherein each of the plurality of support structures include a first support structure and a second support structure of a line shape, and a third support structure of a hole type.

11. The semiconductor device of claim 10, wherein a width of the first support structure and a width of the second support structure are different from each other.

12. The semiconductor device of claim 10, wherein the sacrificial layer extends in the horizontal direction along a sidewall of the first support structure and the second support structure.

13. The semiconductor device of claim 10, wherein the sacrificial layer surrounds a lower end portion sidewall of the third support structure.

14. The semiconductor device of claim 9, further comprising:
a vertical structure extending in the horizontal direction by passing through the stack on the contact region.

15. The semiconductor device of claim 14, wherein the sacrificial layer extends along a lower end portion sidewall of the vertical structure.

16. A method of manufacturing a semiconductor device, the method comprising:
forming a lower end stack in which a plurality of first lower end material layers and at least one second lower end material layer are alternately stacked on a substrate including a cell region and a contact region;
forming a plurality of trenches passing through the lower end stack on the contact region;
forming a sacrificial layer in the plurality of trenches;
forming an upper end stack in which a plurality of first upper end material layers and a plurality of second upper end material layers are alternately stacked on the sacrificial layer and the lower end stack; and
forming first holes for forming a contact plug, trenches for forming a first support structure, and second holes for forming a second support structure passing through the upper end stack and the sacrificial layer on the contact region, together.

17. The method of claim 16, wherein a lower end portion sidewall of the first holes is used for forming the contact plug, a lower end portion sidewall of the trenches is used for forming the first support structure, and a lower end portion sidewall of the second holes is used for forming the second support structure passing through the upper end stack and the sacrificial layer on the contact region contact the sacrificial layer.

18. The method of claim 16, further comprising:
forming contact plugs by filling the first holes with a barrier layer and a gate conductive layer; and
forming the first support structures and the second support structures by filling an insulating layer in the trenches for forming the first support structure and the second holes for forming the second support structure.

19. The method of claim 18, wherein the sacrificial layer surrounds a lower end portion sidewall of the contact plugs, a lower end portion sidewall of the first support structures, and a lower end portion sidewall of the second support structure.

20. The method of claim 18, wherein the first support structures are formed in a line shape, and widths of each of the first support structures are different from each other.
